(19) United States
(12) Patent Application Publication
(10) Pub. No.: US 2012/0270023 A1
(43) Pub. Date: Oct. 25, 2012

(54) COMPOSITE MATERIAL

(76) Inventors: Frank Templin, Herdecke (DE); Dimitrios Peros, Siegen (DE); Tobias Titz, Haan (DE); Harald Küster, Schwelm (DE)

(21) Appl. No.: 13/517,305

(22) PCT Filed: Jul. 16, 2010
(86) PCT No.: PCT/EP2010/060328

§ 371 Date: Jun. 21, 2012

(30) Foreign Application Priority Data
Dec. 21, 2009 (EP) 09180098.7

(51) Int. Cl. B32B 7/02; B32B 5/02; B32B 15/20; C23C 14/34; B05D 5/06; C23C 16/44; C23C 14/30; B32B 15/04; C25D 7/00; B82Y 30/00

(52) U.S. Cl. 428/216; 428/450; 428/457; 428/472; 428/336; 428/220; 205/50; 204/192.28; 427/162; 427/585; 427/596; 204/192.11; 977/755

(57) ABSTRACT

A composite material including a carrier g of aluminum, an optically effective multi-layer system applied to a side (A) of the carrier. The system having at least 2 dielectric and/or oxidic layers, namely an upper layer and a lower, light-absorbing layer. The lower, light-absorbing layer contains a titanium-aluminum mixed oxide TiAl_{q}Oₓ and/or a titanium-aluminum makes nitride TiAl_{q}N_{y} and/or a titanium-aluminum mixed oxynitride TiAl_{q}OₓN_{y}, while the upper layer is an oxidic layer made of titanium, silicon or tin of the chemical composition TiO_{z}, SiO_{w}, or SnOᵥ, where the indices q, v, w, y and z each denote a stoichiometric or nonstoichiometric ratio.

### BACKGROUND

1. Field of the Invention

The invention generally relates to a composite material having a carrier, on which an optically effective multilayer system is applied to one side.

2. Description of Related Technology

In general, an object upon which radiation falls splits this radiation into a reflected component, an absorbed component and a transmitted component, which are defined by the reflectance (reflection capacity), the absorbance (absorption capacity) and the transmittance (transmission capacity) of the object. The reflection capacity, absorption capacity, and transmission capacity are optical properties that can assume different values depending on the wavelength of the incident radiation (for example, within the ultraviolet range, within the range of the visible light, within the infrared range, and within the range of the heat radiation) for one and the same material. Kirchhoff's law, which states that the absorbance is at a constant ratio with respect to the emissivity at a particular temperature and wavelength, applies with respect to the absorption capacity. The Wiensch law of displacement and/or Planck's law are thus also important for the absorption capacity, in addition to the Stefan-Boltzmann law, which describes specific relationships between the radiation intensity, spectral distribution density, wavelength and temperature of a so-called “black body.” When making any related calculations it must be noted that the “black body” as such does not exist, and that real substances will deviate in a characteristic manner from the ideal distribution.

The greatest possible reflectance within one wavelength range of incident radiation is desired in specific application cases, and the smallest possible reflectance, but instead all the more a greater absorbance, is desired within other ranges. This is so in the field of solar collectors, for example, where a maximum absorbance is desired within the solar wavelength range (roughly 300 to 2500 nm), and a maximum reflectance is desired within the range of thermal radiation (above about 2500 nm). The values of solar absorbance (α (AM 1.5)) and thermal emissivity (ε (373 K) determined according to DIN 5036 (Part 3) represent one measure for this spectral selectivity.

Absorbers for flat collectors, which use a composite material that satisfies these requirements, are known under the name Tinox®. This material consists of a carrier consisting of a copper band, a layer of titanium oxynitride applied thereon, and a cover layer of silicon dioxide.

From EP 1 217 394 A1 is furthermore known a composite material of the kind described above, which comprises a carrier made of aluminum, an intermediate layer located on one side of the carrier, and an optically effective multilayer system applied on the intermediate layer. The intermediate layer is preferably made from anodic oxidized or electrolytic polished and anodic oxidized aluminum formed from the carrier material. The optically effective multilayer system consists of three layers, wherein the two top layers are dielectric and/or oxidic layers, and the bottom layer is a metal layer applied on the intermediate layer. It is provided herein that the top layer of the optical multilayer system is a dielectric layer, preferably an oxidic, fluoridic or nitridic layer with chemical composition MeOₐ, MeF_{b}, MeN_{c}, with a refractive index n<1.8 and the middle layer of the optical multilayer system is a chromium oxide layer with chemical composition CrO_{z}, and the bottom layer of the optical multilayer system is made of gold, silver, copper, chromium, aluminum and/or molybdenum, wherein the indices a, b, c and z indicate a stoichiometric or non-stoichiometric ratio in the oxides, fluorides or nitrides. A composite material is thus created, with which the absorbance and reflectance can be selectively and specifically adjusted within different wavelength ranges. The known composite material is moreover also characterized by a good processability, in particular malleability, a high thermal conductance, as well as also a long-term high thermal and chemical resistance. The finishing technique for this material consists of two different processes, which can both be continuously operated, specifically the production of an intermediate layer in a wet-chemical process, which is known generically as anodization and comprises an electrolytic polishing as well as an anodic oxidation, and the application of the optically effective multilayer system in a vacuum.

From DE 10 2004 019 061 B4 is known a selective absorber for conversion of sunlight into heat, in which it is provided that two layer systems are applied onto a substrate, wherein the system located closest to the substrate comprises at least one layer of dense material, that is, a material free of voids of titanium, aluminum, nitrogen, carbon and oxygen having the chemical formula Ti_{α}Al_{β}NₓC_{y}O_{z}, wherein α+β=1 and the ratio of α to β is 1 to 0.05 to 1, and x+y+z=0.8 to 2, and 0.0≦x≦1.2 and 0.2≦y≦2, and 0.05≦z≦2, wherein the second system resting thereon comprises again at least one layer consisting of a mixture of TiO_{z} and Al₂O₃, with 1≦z≦2.

From DE 10 2006 039 669 A1 is known a solar-selective coating with high thermal stability, which can be used for the exploitation of solar energy, which comprises a first solar absorber layer of TiAlN deposited onto a substrate selected from among glass, silicon and a metal, wherein the first absorber layer is covered by an additional second solar absorber layer and a third anti-reflection layer of TiAlON or Si₃N₄.

It is object of the invention create a composite material that is particularly suitable for solar absorbers, which is characterized by simplified production and a high spectral selectivity.

### SUMMARY OF THE INVENTION

This is attained according to the principles of the invention in that the light-absorbing bottom layer contains titanium-aluminum mixed oxide TiAl_{q}Oₓ and/or titanium-aluminum mixed nitride TiAl_{q}N_{y} and/or titanium-aluminum mixed oxynitride TiAl_{q}OₓN_{y}, wherein the upper layer is an oxidic layer made of titanium, silicon or tin having the chemical composition TiO_{z}, SiO_{w} or SnOᵥ, wherein the indices q, v, w, y and z each identify a stoichiometric or non-stoichiometric ratio.

The stoichiometric or non-stoichiometric ratios q, x, y can be herein within the range of 0<q and/or x and/or y<3, while the values of the indices v, w, z can be within the range of 1<v and/or w and/or z≦2, preferably within the range of 1.9≦v and/or w and/or z≦2.

It was surprisingly discovered that a solar absorbance (α (AM 1.5)) of more than 94 percent measured according to DIN 5036 (Part 3) and a thermal emission (ε (373 K)) of less than 6 percent can be achieved with a composite material of this kind, in particular with a carrier of copper or aluminum.

An intermediate layer can be located beneath the optically effective multilayer system in particular on a carrier of aluminum. If this intermediate layer consists of aluminum oxide and rests on an aluminum carrier, inventive significance is then attributed to the feature that the thickness of the intermediate layer is not greater than 30 nm, regardless of whether the lower light-absorbing layer contains titanium-aluminum mixed oxide TiAl_{q}Oₓ and/or titanium-aluminum mixed nitride TiAl_{q}N_{y} and/or titanium-aluminum mixed oxynitride TiAl_{q}OₓN_{y}, and whether the upper layer is an oxidic layer of titanium, silicon or tin having the chemical composition TiO_{z}, SiO_{w} or SnOᵥ. It will suffice herein that the upper layer is a dielectric layer with a refractive index of less than 1.7. However, it can be higher, such as, for example, in the case of a tin oxide layer at about 1.9 or in a titanium dioxide layer at about 2.55 (Anatas) or 2.75 (Rutil).

It was surprisingly discovered that the intermediate layer displays, not only the known effect of mechanical and corrosion-inhibiting protection for the carrier and high adhesion for the optical multilayer system resting thereon, but rather also that the intermediate layer and the carrier can thereby also be optically effective themselves, if the intermediate layer is made from aluminum oxide having an extremely small thickness within the range according to the invention of no more than 30 nm, in particular a thickness within the range of at least 3 nm, and preferably a thickness within the range of 15 nm to 25 nm. The intermediate layer has then an advantageously high transmission capacity and the carrier has such a high reflection capacity triggered by the transmission of the intermediate layer, that the bottom metal layer of the optical multilayer system known from EP 1 217 394 A1 can be omitted without loss of efficiency. The technological step of applying a layer can thus be omitted on the one hand, and a savings in materials is attained on the other hand, in particular a savings of the noble metals, gold and silver, or even of the likewise expensive molybdenum, which are preferably used for the bottom metal layer.

The optical multilayer system according to the invention can be initially advantageously applied—just as with the known composite material—in such a way that the use of at times toxic salt solutions, which are harmful to the environment, can be omitted during the production. However—as was already mentioned—the metal layer of the known optical multilayer system can likewise be omitted, so that the production expense is reduced.

The layers of the optical multilayer system can be sputter layers, in particular layers produced by reactive sputtering, CVD or PECVD layers or layers produced by vapor deposition, in particular by means of electron bombardment, or layers produced from thermal sources, so that the entire optical multilayer system consists of layers applied in a vacuum sequence, in particular in a continuous method.

In the case in which an extremely thin aluminum oxide layer is applied on an aluminum carrier, it can also be advantageously provided that the bottom layer contains chromium oxide having the chemical composition CrOᵣ and/or chromium nitride having the chemical composition CrNₛ and/or chromium oxynitride having the chemical composition CrOᵣNₛ, wherein the indices r and s each identify a stoichiometric or non-stoichiometric ratio.

The top layer can be preferably be in each case a silicon oxide layer having the chemical composition SiO_{w}, wherein the index w also here indicates a stoichiometric or non-stoichiometric ratio in the oxidic composition.

The mentioned methods advantageously allow therein an adjustment of the chemical composition of the layers with respect to the indices r, s, q, v, w, x, y and z, not only to specific discrete values, but rather also a variation of the particular stoichiometric or non-stoichiometric ratio within specific limits, either in a continuous or gradual manner via the layer thickness. In this way, the refractive index of the top reflection-reducing layer—which also causes an increase in the values for mechanical resistance (DIN 58196, part 5)—and the absorption of the bottom layer, for example, can be specifically adjusted, wherein, for example, the absorption capacity decreases with an increasing value of the indices x and/or y. The respective proportions of titanium-aluminum mixed oxide, nitride and/or oxynitride and/or the proportions of the corresponding chromium compounds in the bottom layer can also be managed in this way.

According to the invention, an overall light reflectance determined on the side of the optical multilayer system according to DIN 5036, Part 3, can be adjusted to a preferred value of less than 5%.

Due to its synergistic combination of properties, the invented composite material has excellent utility for absorbers in solar collectors because of
The carrier layer, for example, its excellent malleability with which it can withstand the stress of subsequent processing during the shaping procedure, for example, its high thermal conductance and ability to take on a surface structure with promotes absorption in the solar wavelength range, and then following the other layers in a relief, and which has additionally—as stated above—a high reflectivity metal and thus low emission and this takes account of the fact that the radiation power is made available as storable heat energy;
The bottom layer with its high selectivity of absorption (peak values over 90% in the solar range, or over 94% in the presence of the titanium-aluminum compounds, minimum values below 15% in the wavelength range > about 2500 nm) and the already explained ease of modification of the chemical composition, and
The top, in particular silicon oxide layer, whose advantages were already in part referred to above, and the additional dereflective effect and high transmission capacity, and thus increases the percentage of radiation absorbable in the solar range in the bottom layer.

Further advantageous embodiments of the invention are contained in the dependent claims and in the following detailed description.

### BRIEF DESCRIPTION OF THE DRAWINGS

The invention will be explained in greater detail based on several exemplary embodiments illustrated in the figures, wherein:

FIG. 1 shows a first embodiment in basic cross sectional representation through the composite material according to the principles of the present invention;

FIG. 2 shows a second embodiment in basic cross sectional representation through the composite material according to the principles of the invention; and

FIG. 3 shows a third embodiment of a basic cross sectional representation through the composite material according to the principles of the invention.

### DETAILED DESCRIPTION

The same and corresponding parts are identified with the same reference numbers in the figures, so that each is described only once.

The described embodiments concern a composite material according to the principles of the invention having a high selectivity of absorbance and reflectance within the solar wavelength range and within the range of thermal radiation.

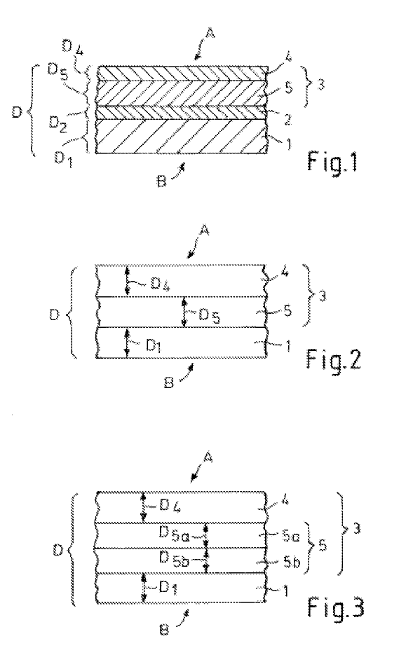

The composite material shown in the embodiment of FIG. 1 includes an especially malleable strip-shaped carrier 1 made of aluminum, an intermediate layer 2 located on side A of the carrier 1, and an optically effective multilayer system 3 applied on the intermediate layer 2.

A total light reflectance determined according to DIN 5036, Part 3, is less than 5% on side A of the optical multilayer system 3.

The composite material can be preferably configured as a coil with a width of up to 1600 mm, preferably 1250 mm, and with a thickness D of about 0.1 to 1.5 mm, preferably about 0.2 to 0.8 mm. The carrier 1 can have preferably a thickness D₁ of about 0.1 to 0.7 mm.

The aluminum of carrier 1 can have in particular a purity higher than 99.0%, so that its thermal conductance is promoted.

The intermediate layer 2 can be made of aluminum oxide—applied in particular by means of anodic oxidation onto the carrier material—and has a thickness D₂ of no more than 30 nm.

The multilayer system 3 comprises at least two single layers 4, 5, and particularly preferably exclusively two single layers 4, 5.

The top layer 4 of the optical multilayer system 3 is a silicon oxide layer having the chemical composition SiO_{w}. It had therefore a refractive index of less than 1.7.

The bottom layer 5 is a light-absorbing layer preferably containing titanium-aluminum mixed oxide and/or titanium-aluminum mixed nitride and/or titanium-aluminum mixed oxynitride having the chemical composition TiAl_{q}OₓN_{y}.

This layer 5 can also contain chromium oxide having the chemical composition CrOᵣ and/or chromium nitride having the chemical composition CrNₛ and/or chromium oxynitride having the chemical composition CrOᵣNₛ.

The indices r, s, q, x, y indicate herein a stoichiometric or non-stoichiometric ratio of the oxide or nitride substance to the oxygen in the oxides and/or in the oxynitride and/or of the aluminum to titanium, respectively. The stoichiometric or non-stoichiometric ratios can be preferably within the range of 0<q and/or v and/or x and/or y and/or z<3, whereas the stoichiometric or non-stoichiometric ratio w can take on values within the range of 1≦w≦2, preferably within the range of 1.9≦w≦2.

Because the two layers 4, 5 of the optical multilayer system 3 can be sputter layers, in particular layers produced by means of reactive sputtering, CVD or PECVD layers, or layers produced by means of vapor deposition, in particular by electron bombardment, or from thermal sources, it is possible to adjust the ratios q, v, w, x, y, z in a gradual or non-gradual manner (thus also to non-stoichiometric values of the indices), so that the particular layer properties can be varied and the layers can also be configured as gradient layers with indices q, v, w, x, y, z increasing and/or decreasing across the layer thickness.

The minimum thickness D₂ of the intermediate layer 2 is determined by the technological limits of the method employed to produce the intermediate layer 2 and can be at 3 nm. The thickness D₂ of the intermediate layer is preferably, however, within the range of 15 nm to 25 nm.

In this connection, it should be mentioned that the intermediate layer 2 can also be produced by means of the method, which is preferably used to produce the layers 4, 5 of the optical multilayer system 3. In this case the ratio of oxygen to aluminum within the layer can likewise be not only a stoichiometric, but also a non-stoichiometric one.

Especially because the intermediate layer 2 is formed by anodic oxidation or electrolytic polishing and anodic oxidation from the carrier material, wherein an oxide layer naturally present on the aluminum surface is removed by etching, an absence of grease, a high coatability and adhesion of the layers 4, 5 above, can be achieved.

The upper layer 4 of the optical multilayer system 3 can preferably have a thickness D₄ of more than 3 nm. With this thickness D₄, the layer already has sufficient efficiency, wherein time, material and energy expenditure assume only small values. From this point of view, an upper limit for the layer thickness D4 would be at about 500 nm.

An optimum value for the lower layer 5 of the optical multilayer system 3 under the stated circumstances is a minimum thickness D₅ of more than 50 nm, with a maximum of about 1 μm.

The side B of the strip-shaped carrier 1 facing away from the optical multilayer system 3 can remain uncoated, or—like the intermediate layer 2—can be made of anodic oxidized or electrolytic polished and anodic oxidized aluminum, for example.

In the second embodiment of the invention shown in FIG. 2, the composite material again has a carrier 1 preferably made of copper or aluminum, on whose side A an optically active multilayer system 3 has been applied, which consists exclusively of two dielectric and/or oxidic layers 4, 5, namely an upper layer 4 and a lower light-absorbing layer 5. The lower layer 5 contains and can be made exclusively of titanium-aluminum mixed oxide TiAl_{q}Oₓ and/or titanium-aluminum mixed nitride TiAl_{q}N_{y} and/or titanium-aluminum mixed oxynitride TiAl_{q}OₓN_{y}. The upper layer 4 is an oxidic layer of titanium, silicon or tin having the chemical composition TiO_{z}, SiO_{w} or SnOᵥ. The indices q, v, w, y and z each indicate a stoichiometric or non-stoichiometric ratio. The lower layer 5 of the optical multilayer system 3 has preferably a thickness D₅, which is within the range between 50 nm and 150 nm. The thickness D₄ of the upper layer 4 is within the same range as in the first embodiment. A solar absorbance (α (AM 1.5)) of more than 94 percent determined according to DIN 5036 (Part 3) and a thermal emissivity (ε (373 K)) of less than 6 percent was achieved in this kind of composite material. The two layers 4, 5 of the optical multilayer system 3 can be—as in the first embodiment—layers in which the indices q, v, w, x, y and/or z change across the particular thickness D₄, D₅.

The composite material according to the third embodiment of the invention, shown in FIG. 3, has the same structure as the second embodiment of the invention with regard to the carrier 1 and the upper layer 4. The specific difference of this embodiment consists in that the lower layer 5 of the optical multilayer system 3 has at least of two partial layers 5a, 5b, of which one partial layer 5a, 5b can be nearly free of oxygen or nitrogen. It is especially provided that the lower layer 5 of the optical multilayer system 3 consists of precisely two partial layers 5a, 5b, wherein the lower part layer 5b consists of titanium-aluminum mixed oxide TiAl_{q}Oₓ, and the upper partial layer 5a consists of titanium-aluminum mixed oxynitride TiAl_{q}OₓN_{y}. The lower partial layer 5b can also have a non-oxidic, in particular purely metallic character in that it is made of titanium-aluminum alloy.

The two partial layers 5a, 5b can each have a thickness D₅ₐ, D_{5b} within the range of 20 nm to 80 nm. A solar absorbance (α (AM 1.5)) of more than 94 percent determined according to DIN 5036 (Part 3) and a thermal emissivity (ε (373 K)) of less than 6 percent are also achieved with a composite material of this kind.

The invention is not limited to the illustrated exemplary embodiments, but rather includes also all equivalent means and methods within the scope of the invention. Where the term “oxidic” is used in the application, it is understood, on the one hand, that it is: “oxygen containing,” which does not rule out the presence of additional elements. This means for the top layer 4 that the latter—for example when referred to silicon—that it can be made of silicon oxycarbide or carboxide or a silicon oxycarbonitride or carboxynitride. To this effect, the term “oxidic” is also understood according to the invention to mean “oxidized” within the meaning of an increase in oxidation number compared to the elementary state, so that it is possible, for example, within the framework of the invention, that the top layer 4 alternatively also features a purely fluoridic or nitridic nature.

With regard to what concerns the lower light-absorbing layer 5 and/or its partial layers 5a, 5b, which contain or contains titanium-aluminum mixed oxide TiAl_{w}Oₓ and/or titanium-aluminum mixed nitride TiAl_{q}N_{y} and/or titanium-aluminum mixed oxynitride TiAl_{q}OₓN_{y}, this composition does not rule out that additional elements, in particular carbon, might be present in these ternary or quaternary systems. Carbon, for example, can be contained in a proportion of 0 to 10 atomic percent.

An intermediate layer 2 having optical effectiveness, a barrier effect and/or which functions as an adhesion promoter, which is necessarily present in the first embodiment of the invention, can optionally also be present in a composite material of the kind defined in the second or third exemplary embodiment. The intermediate layer 2 need not necessarily be made from aluminum oxide. It can also be made of a different, in particular a sputtered, metal oxide, for example TiO₂.

The invention does not rule out the presence of additional layers in the layer system, even though preferably only the layers described above should be present, since they interact in a synergistically optimum manner to attain the object of the invention. Especially the presence of a metal reflection layer can be omitted from the optical multilayer system.

The invention is furthermore not restricted to the feature combination defined in claims 1 and 5, but can rather be defined by any other particular combination of specific features of all disclosed individual features. This means that basically practically any individual feature of the referenced claims can be omitted or replaced by at least another single feature disclosed elsewhere in the application. The claims are to be understood to this extent merely as an initial attempt at formulating the invention.

1. A composite material comprising a carrier on whose one side (A) is applied an optically effective multilayer system having at least two dielectric and/or oxidic layers, the at least two dielectric and/or oxidic layers including an upper layer and a lower light-absorbing layer, wherein the lower light-absorbing layer contains titanium-aluminum mixed oxide TiAl_{q}Oₓ and/or titanium-aluminum mixed nitride TiAl_{q}N_{y} and/or titanium-aluminum mixed oxynitride TiAl_{q}OₓN_{y}, wherein the upper layer (4) is an oxidic layer made of titanium, silicon or tin having the chemical composition TiO_{z}, SiO_{w} or SnOᵥ, where the indices q, v, w, x, y and z each indicate a stoichiometric or non-stoichiometric ratio.

2. The composite material of claim 1, wherein the indices for the stoichiometric or non-stoichiometric ratios q, x, y are within a range from 0<q and/or x and/or y<3.

3. The composite material of claim 1, wherein the indices for the stoichiometric or non-stoichiometric ratios v, w, z are within a range from 1<v and/or w and/or z≦2, preferably within the range from 1.9≦v and/or w and/or z≦2.

4. The composite material of claim 1, wherein the carrier is made of copper or aluminum.

5. The composite material of claim 1, wherein the carrier is made of aluminum, and wherein an intermediate layer made of aluminum oxide and having preferably a thickness (D₂) of no more than 30 nm is located underneath the optically effective multilayer system, and wherein the upper layer is a dielectric layer with a refractive index of less than 1.7.

6. The composite material of claim 5, wherein the intermediate layer has a thickness (D₂) within the range of 15 nm to 25 nm.

7. The composite material of claim 5, wherein the intermediate layer is made of anodic oxidized or electrolytic polished and anodic oxidized aluminum, which is formed from the carrier material.

8. The composite material of claim 5, wherein the lower layer contains chromium oxide having the chemical composition CrOᵣ and/or chromium nitride having the chemical composition CrNₛ and/or chromium oxynitride having the chemical composition CrOᵣNₛ, wherein indices r and s each indicate a stoichiometric or non-stoichiometric ratio.

9. The composite material of claim 8, wherein the indices for the stoichiometric or non-stoichiometric ratios r, s are within the range of 0<r and/or s<3.

10. The composite material of claim 1, wherein the at least two dielectric and/or oxidic layers of the optical multilayer system are sputter layers, in particular layers produced by means of one of reactive sputtering, CVD or PECVD layers, or are formed by vapor deposition, produced by means of electron bombardment or from thermal sources.

11. The composite material of claim 1, wherein the optical multilayer system includes layers applied in a vacuum sequence in a continuous method.

12. The composite material of one of claim 1, wherein the upper layer of the optical multilayer system has a thickness (D₄) of more than 3 nm and a maximum of about 500 nm.

13. The composite material of claim 1, wherein the upper layer and/or the lower layer of the optical multilayer system contain carbon and/or nitrogen.

14. The composite material of claim 1, wherein the lower layer of the optical multilayer system has a thickness (D₅) of more than 50 nm and a maximum of about 1 μm, wherein this thickness (D₅) is within the range between 50 nm and 150 nm.

15. The composite material of claim 8, wherein the indices r, s, q, v, w, x, y and/or z indicating the stoichiometric or non-stoichiometric ratios change continuously or sharply across the thickness (D₄, D₅) of the particular layer in one or a plurality of the layers of the optical multilayer system.

16. The composite material of claim 1, wherein the lower layer of the optical multilayer system includes at least two partial layers (5a, 5b), of which one partial layer is nearly free of oxygen or nitrogen.

17. The composite material of claim 16, wherein the lower layer of the optical multilayer system includes a lower partial layer and an upper partial layer, wherein the lower partial layer is formed from titanium-aluminum mixed oxide TiAl_{q}Oₓ and the upper part layer is formed from titanium-aluminum mixed oxynitride TiAl_{q}OₓN_{y}.

18. The composite material of claim 16, wherein the lower layer of the optical multilayer system includes a lower partial layer and an upper partial layer, wherein the lower partial layer is made of titanium-aluminum alloy.

19. The composite material of claim 17, wherein the two partial layers each have a thickness (D₅ₐ, D_{5b}) within the range of 20 nm to 80 nm.

20. The composite material of claim 1, wherein a total light reflectance determined according to DIN 5036, Part 3, at side (A) of the optical multilayer system is less than 5%.

21. The composite material of claim 1, wherein a solar absorbance (α (AM 1.5)) determined according to DIN 5036, Part 3, is more than 94 percent, and a thermal emissivity (ε (373 K) is less than 6 percent.

22. The composite material of claim 1, having a configuration as a coil having a width of up to 1600 mm, and having a thickness (D) of about 0.1 to 1.5 mm.

23. The composite material of claim 1, having a configuration as a coil having a width of about 1250 mm and a thickness of about 0.2 to 0.8 mm.

24. The composite material of claim 5, wherein the intermediate layer has a thickness (D₂) of at least 3 nm.

25. The composite material of claim 1, wherein the indices q, v, w, x, y and/or z indicating the stoichiometric or non-stoichiometric ratios change continuously or sharply across the thickness (D₄, D₅) of at least one of the dielectric and/or oxidic layers of the optical multilayer system.
